(19) United States
(12) Patent Application Publication
(10) Pub. No.: US 2017/0179369 A1
(43) Pub. Date: Jun. 22, 2017

(54) PLATFORM COMMUNICATIONS THROUGH PIEZOELECTRIC VIBRATIONS IN A PCB MEDIUM

(71) Applicant: Intel Corporation, Santa Clara, CA (US)

(72) Inventors: Sergio GARCIA DE ALBA GARCIN, Tlajomulco (MX); Hector A. CORDOURIER MARURI, Guadalajara (MX); Alfredo CUEVA GONZALEZ, Zapopan (MX); Jesus H. ALVAREZ MONROY, Tlaquepaqueme (MX); Juan F. RAMIREZ AGUILAR, Tlajomulco de Zuniga (MX)

(21) Appl. No.: 14/974,593

(22) Filed: Dec. 18, 2015

(51) Int. Cl. H01L 41/113; H01L 41/09

(52) U.S. Cl. CPC H01L 41/1132; H01L 41/09

(57) ABSTRACT

A system and method of communicating among electronic devices on a platform. The method includes inducing, at a first device coupled to a substrate, mechanical vibrations in the substrate. Then the method further includes receiving the mechanical vibrations through the substrate at a second device coupled to the substrate. The mechanical vibrations are interpreted as a command to the second device. The second device acts on the command.

### BACKGROUND

Field

Embodiments of the invention relate to communication between components on a substrate. More specifically, the invention relates to use of mechanical vibrations in the substrate as a communication channel between components on the substrate.

Background

Many cases exist where devices on a platform would like to transmit low data rate messages to other devices on the platform. This is typically done using electrical connections between all of the devices. But, this significantly increases the board complexity and, in some cases, increases the required number of layers in printed circuit board (PCB) design. The increased routing complexities and possibly increased number of layers increase the cost and lower the yield for any particular platform.

### BRIEF DESCRIPTION OF THE DRAWINGS

Embodiments of the invention are illustrated by way of example and not by way of limitation in the figures of the accompanying drawings in which like references indicate similar elements. It should be noted that different references to “an” or “one” embodiment in this disclosure are not necessarily to the same embodiment, and such references mean at least one.

FIG. 1 is a block diagram of an apparatus according to one embodiment of the invention.

FIG. 2 is a block diagram of a system according to one embodiment of the invention.

FIGS. 3A and 3B are flow diagrams of transmission and reception in a communication channel according to one embodiment of the invention.

### DETAILED DESCRIPTION

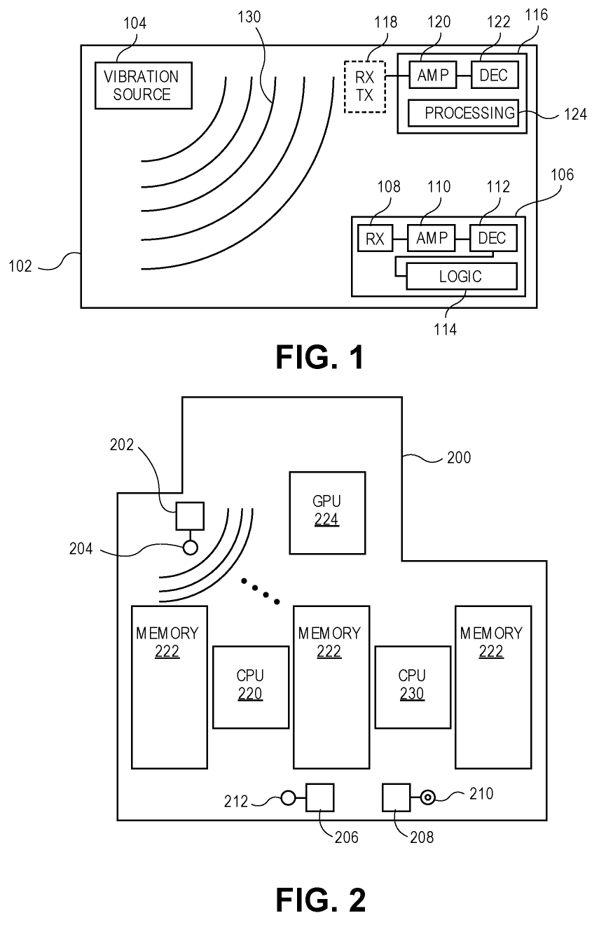

FIG. 1 is a block diagram of an apparatus according to one embodiment of the invention. Substrate 102 has a vibration source 104 coupled thereto. Substrate 102 may be, for example, a printed circuit board (PCB). Vibration source 104 induces mechanical vibrations 130 in substrate 102. Possible vibration sources include servos, electrostatic membranes, piezoelectric elements; and the like. Piezoelectric elements, e.g. quartz crystals are particularly desirable due to their small size and that they can either be embedded within the substrate or coupled to the surface thereof. Properly controlled, the vibration source 104 can encode data in mechanical vibrations 130. In this way, it can communicate with other devices on the substrate with which no electrical signal path exists. This has the advantage of reducing routing requirements where low data rates are sufficient. Examples include: turning devices on the board on or off; central processing unit (CPU) side-band communications; enables; status checks; fan control; and the like. Additionally, signal transmission is not effected by electrical noise or communication voltage level. This allows communication in electrically noisy environments and without voltage level translation.

One manner in which data may be encoded in vibrations 130 is on-off keying (OOK). Error correction information may also be included in the encoded data. FIG. 1 shows two receiving devices 106 and 116 coupled to substrate 102. Device 106 includes a vibration sensor 108 which may be, for example, a piezoelectric sensor. Sensor 108 includes a transducer that receives the mechanical vibrations 130 and converts them into electrical signals. Those electrical signals are then passed to a low noise amplifier 110, which amplifies the signals and passes them to a decoder 112. The decoder 112 decodes the electrical signals and passes them to processing logic 114 to act on the command or message decoded.

Device 116 includes a vibration transceiver 118 which is able to both receive vibrations and transmit a response. By inducing its own vibrations in the substrate 102, a half-duplex communication channel can be created between vibrations source 104 and device 116. Device 118 may be a piezoelectric element embedded in substrate 102, or a combination of vibration receivers and vibration sources responsive to some controller. When the vibrations are received at receiver 118, a transducer converts the vibrations to electrical signals and passes them to amplifier 120. Amplifier 120 may be a low noise amplifier that amplifies these electrical signals and passes them to decoder 122. Decoder 122 decodes the electrical signals and passes them to processing logic 124 to act on those signals. Processing logic 124 may then drive the transmitter portion of transceiver 118 to send a reply to the vibration source 104, where vibration source 104 expects to receive responses that may include a vibration sensor, amplifier and decoder to receive such responses and covert them to data. To ensure effective communication, vibration frequency is chosen to propagate through the PCB without significant effect from other mechanical noises that are commonly present. Typical noise sources include, without limitation, cooling fans, electric motors, and the like. The tested frequency range of vibration transmission possible in a PCB medium is from 500 Hz to 300 kHz. The frequency is selected in this range depending on the actuator (piezoelectric/piezotronic device) resonance, which is usually within this range given.

The amplifiers 110 and 120 compensate for the displacement transmissibility present in the board. For FR-4 PCB, displacement transmissibility is proportional to the square root of the natural frequency, Q=C\sqrt{F}n, where C is a constant with a value usually in the range of 0.5-2 depending on the board size. This results in a typical Q value of approximately 20. Assuming a 360° vibration propagation displacement transmissibility in the receiver, and assuming 1 mm between the pins in the receiving device, and a distance of 0.5 m from the broadcasting device (which corresponds to a relatively large but feasible distance found in datacenter PCBs),

$${disp}_{fraction} = \frac{.1 cm}{2 π \cdot 50 cm} \cdot 20 = .00636 ,$$

which results in an attenuation level that can be overcome by the amplifier. Empirically, the speed of that the vibrations travel through the board has been found to be approximately 3900 m/s. Assuming distances better transmitter and receiver of fifteen centimeters yields an effective bit rate of 2.5 kilobits per second. This is sufficiently fast to handle most miscellaneous and static control signals on most platforms. Generally, data rates between one kilobit and 2.5 kilobits are achievable on most practical platforms.

FIG. 2 is a block diagram of a system according to one embodiment of the invention. A substrate 200 has a plurality of central processing units 220 and 230 coupled thereto. Substrate 200 may be a printed circuit board (PCB). A graphics processing unit (GPU) 224 may be coupled to the substrate 200. Also coupled thereto are a plurality of memory modules 222.

A pair of fan controllers 206 and 208 is also coupled to substrate 200. Coupled to each fan controller are piezoelectric sensors 212 and 210 that operate in the manner described with reference to FIG. 1. Piezoelectric sensor 210 is shown mounted on a mounting hole. Notably, piezoelectric sensors exist with mounting hole on them, so by mounting sensor 210 on a mounting hole, no board real estate is consumed by the sensor 210. As previously noted, sensors 210 and 212 could be embedded in the substrate 200.

A controller such as board controller 202 is coupled to a piezoelectric transceiver 204. Board controller 202 drives transceiver 204 to induce mechanical vibrations in the board 200 to send commands to the fan controllers 206, 208 with which it has no electrical signal path. For example, signals to increase or decrease the fan speed can be sent from board controller 202 to fan controller 206 or 208 via the mechanical vibrations. Using the half-duplex link, fan controllers 206 and 208, via their respective piezoelectric transceivers 212 and 210, can send back fan tachometer readings or other status data. All of the foregoing may be encoded using OOK, and error correction code information can be included. In this example, fan control is accomplished without any electrical routing and is independent of the location of the fan controllers relative to the board controller. Other devices (not shown) on the substrate may also access the mechanical communication channel for enables, status checks and the like.

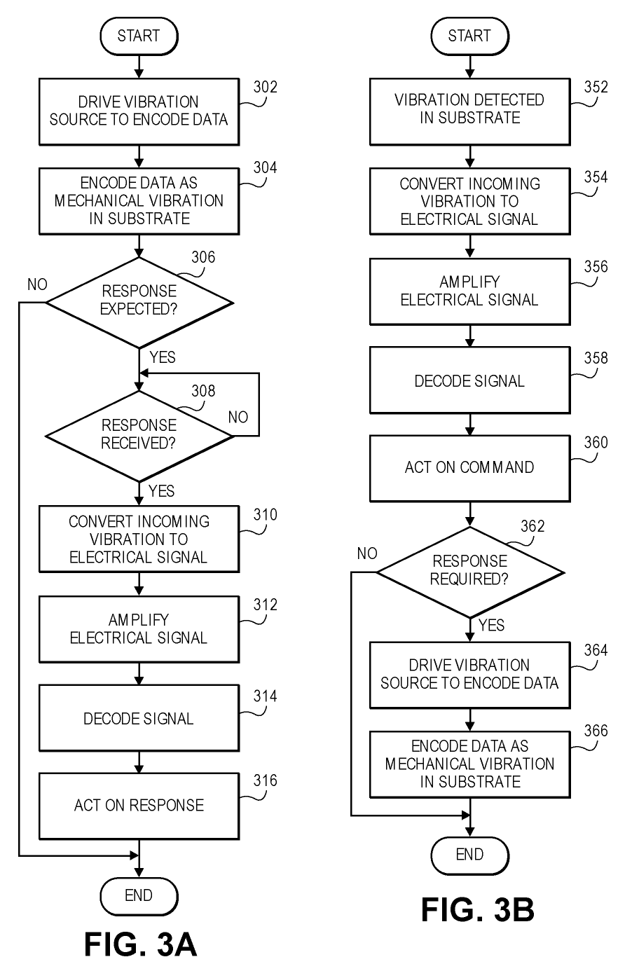

FIGS. 3A and 3B are flow diagrams of transmission and reception in a communication channel according to one embodiment of the invention. At block 302, a controller or other logic drives the vibration source to encode data. At block 304, data is encoded as mechanical vibrations in the substrate. The vibration source induces those vibrations responsive to the direction of the controller. In some embodiments, OOK is used for this encoding. Other encoding are within the scope and contemplation of other embodiments of the invention.

At block 306, a determination is made whether a response is expected to the data that has been driven. If a response is expected, a determination is made at decision block 308 whether the response has been received. If the response has been received at block 308, incoming mechanical vibrations are converted to electrical signals at block 310. For example, a piezoelectric transducer may be used to convert the vibrations into attenuated electrical signals. Those signals are amplified using a low noise amplifier at block 312. The electrical signals are decoded at block 314, and the vibrations source (or its controller) acts on the response at block 316. If no response is expected at block 306, or after action on the response, the process ends.

In FIG. 3B, the receiver detects a vibration in the substrate at block 352. Upon detecting the vibration of the substrate, that incoming vibration is converted to an electrical signal at block 354. The converted signal is then amplified at block 356. The amplified signal is decoded at block 358. At block 360, the receiver acts on the data received by, for example, increasing or decreasing fan speed, turning on or off the controlled device, or the like. A determination is then made at block 362 whether a response is required. If a response is required (when vibrations are no longer being received), at block 264 the local controller drives the receiver to encode data as vibrations. At block 366, the receiver induces vibrations in the substrate to encode that data. The mechanical vibrations propagate through the substrate and are received by a target (potentially, the original sender). If no response is required, or after sending the required response, the routine ends.

The following examples pertain to further embodiments. The various features of the different embodiments may be variously combined with some features included and others excluded to suit a variety of different applications. Some embodiments pertain to a method of communicating among electronic devices on a platform. The method includes inducing, at a first device coupled to a substrate, mechanical vibrations in the substrate. Then the method further includes receiving the mechanical vibrations through the substrate at a second device coupled to the substrate, interpreting the mechanical vibrations as a command to the second device, and acting on the command in the second device.

In further embodiments, a piezoelectric sensor coupled to the second device senses the mechanical vibrations.

In further embodiments, the second device interprets the vibrations by generating electrical signals from the mechanical vibrations, amplifying the electrical signals, and decoding the electrical signals.

In further embodiments, the amplification is a function of a distance between the first device and the second device.

In further embodiments, inducing includes encoding the command in the mechanical vibrations with on-off keying.

In further embodiments, the inducing encodes error correction code information within the vibrations.

Further embodiments include inducing vibrations at the second device to convey data to the first device.

In further embodiments, a mechanical vibration communication channel between the first and second device is half duplexed with the data rate between one kilobit and 2.5 kilobits per second.

Some embodiments pertain to an apparatus having a substrate and a vibration source coupled thereto to induce mechanical vibrations in the substrate. A receiver is coupled to the substrate, the receiver to interpret the mechanical vibrations as a command or message to the receiver.

In further embodiments, the substrate includes a printed circuit board.

In further embodiments, the vibration source includes a piezoelectric device.

In further embodiments, the receiver includes a vibration sensor, an amplifier, and a decoder.

In further embodiments, the vibration sensor includes a piezoelectric sensor to convert mechanical vibrations in an attenuated electrical signal.

In further embodiments, the receiver includes a second vibration source to encode data in the form of mechanical vibrations in the substrate.

In further embodiments, the vibration source is embedded within the substrate.

In further embodiments, the mechanical vibrations to encode one or more commands based on on-off keying with error code correction information.

Some embodiments pertain to a system in which a printed circuit board (PCB) has a plurality of central processing units mounted thereon. A controller is coupled to the PCB and distinct from the central processing units, the controller electrically coupled to a piezoelectric transmitter. At least one controlled device coupled to the PCB is electrically decoupled from the controller, wherein the controller induces mechanical vibrations in the PCB with the piezoelectric transmitter to encode commands to the controlled device.

In further embodiments, the controlled device includes a low noise amplifier and a decoder.

In further embodiments, the controlled device includes a piezoelectric transmitter.

In further embodiments, the controller to encode commands based on-off keying and error correction codes.

Some embodiments pertain to an apparatus including a substrate having means for encoding data as mechanical vibrations in the substrate. A means for receiving the data encoded as mechanical vibrations in the substrate, wherein the means for encoding and the means for receiving are electrically decoupled on the substrate.

In further embodiments, the means for encoding includes means for inducing mechanical vibrations in the substrate.

In further embodiments, the means for receiving includes means for sensing the mechanical vibrations and means for converting the mechanical vibrations into electrical signals.

While embodiments of the invention are discussed above in the context of flow diagrams reflecting a particular linear order, this is for convenience only. In some cases, various operations may be performed in a different order than shown or various operations may occur in parallel. It should also be recognized that some operations described with respect to one embodiment may be advantageously incorporated into another embodiment. Such incorporation is expressly contemplated.

In the foregoing specification, the invention has been described with reference to the specific embodiments thereof. It will, however, be evident that various modifications and changes can be made thereto without departing from the broader spirit and scope of the invention as set forth in the appended claims. The specification and drawings are, accordingly, to be regarded in an illustrative rather than a restrictive sense.

What is claimed is:

1. A method of communicating among electronic devices on a platform, the method comprising:
inducing, at a first device coupled to a substrate, mechanical vibrations in the substrate;
receiving the mechanical vibrations through the substrate at a second device coupled to the substrate;
interpreting the mechanical vibrations as a command to the second device; and
acting on the command in the second device.

2. The method of claim 1, wherein the receiving comprises:
sensing the mechanical vibrations with a piezoelectric sensor coupled to the second device.

3. The method of claim 1, wherein the interpreting comprises:
generating electrical signals from the mechanical vibrations;
amplifying the electrical signals; and
decoding the electrical signals.

4. The method of claim 3, wherein the amplification is a function of a distance between the first device and the second device.

5. The method of claim 1, wherein the inducing comprises:
encoding the command in the vibrations with on-off keying.

6. The method of claim 5, wherein the inducing further comprises:
encoding error correction code information within the mechanical vibrations.

7. The method of claim 1, further comprising:
inducing vibrations at the second device to convey data to the first device.

8. The method of claim 7, wherein a mechanical vibration communication channel between the first and second device is half duplexed with a data rate between one kilobit and 2.5 kilobits per second.

9. An apparatus comprising:
a substrate;
a vibration source coupled to the substrate to induce mechanical vibrations in the substrate;
a receiver coupled to the substrate, the receiver to interpret the mechanical vibrations as a command to the receiver.

10. The apparatus of claim 9, wherein the substrate comprises:
a printed circuit board.

11. The apparatus of claim 9, wherein the vibration source comprises:
a piezoelectric device.

12. The apparatus of claim 9, wherein the receiver comprises:
a vibration sensor;
an amplifier; and
a decoder.

13. The apparatus of claim 12, wherein the vibration sensor comprises:
a piezoelectric sensor to convert the mechanical vibrations in an attenuated electrical signal.

14. The apparatus of claim 9, wherein the receiver comprises:
a second vibration source to encode data in the form of mechanical vibrations in the substrate.

15. The apparatus of claim 9, wherein the vibration source is embedded within the substrate.

16. The apparatus of claim 9, the mechanical vibrations to encode one or more commands based on on-off keying with error code correction information.

17. A system comprising:
a printed circuit board (PCB);
a plurality of central processing units mounted on the PCB;
a controller coupled to the PCB and distinct from the central processing units, the controller electrically coupled to a piezoelectric transmitter; and
at least one controlled device electrically decoupled from the controller, the controller to induce mechanical vibrations in the PCB with the piezoelectric transmitter to encode commands to the controlled device.

18. The system of claim 17, wherein the controlled device comprises:
a low noise amplifier; and
a decoder.

19. The system of claim 18, wherein the controlled device further comprises:
a piezoelectric transmitter.

20. The system of claim 17, the controller to encode the commands based on on-off keying and error correction codes.
